(19) United States
(12) Patent Application Publication
(10) Pub. No.: US 2008/0096357 A1
(43) Pub. Date: Apr. 24, 2008

(54) METHOD FOR MANUFACTURING A MEMORY DEVICE

(75) Inventors: Youseok Suh, Cupertino, CA (US); Hidehiko Shiraiwa, San Jose, CA (US); Allison Holbrook, San Jose, CA (US); Angela Hui, Fremont, CA (US); Kuo-Tung Chang, Saratoga, CA (US)

Correspondence Address: FARJAMI & FARJAMI LLP, 26522 LA ALAMEDA AVENUE, SUITE 360, MISSION VIEJO, CA, 92691, US

(73) Assignees: SPANSION LLC; ADVANCED MICRO DEVICES, INC.

(21) Appl. No.: 11/551,535

(22) Filed: Oct. 20, 2006

(51) Int. Cl. H01L 21/336

(52) U.S. Cl. 438/287; 438/591

(57) ABSTRACT

A method for manufacturing a memory device that includes using a gap-filling material that inhibits charge coupling between memory devices. A semiconductor material is provided that has an active region and an isolation region. A charge trapping structure is formed over the active region and a layer of semiconductor material is formed over the charge trapping structure and the isolation region. A masking structure having sidewalls is formed on the layer of semiconductor material. Spacers are formed adjacent the sidewalls and the layer of semiconductor material is etched to form one or more conductive strips having opposing sides. The one or more conductive strips are formed over the active region. A dielectric material is formed adjacent to the opposing sides of each conductive strip. The dielectric material serves as a gap-filling material. A layer of semiconductor material is formed over the one or more conductive strips.

### FIELD OF THE INVENTION

The present invention relates, in general, to semiconductor components and, more particularly, to semiconductor memory devices.

### BACKGROUND OF THE INVENTION

Semiconductor component manufacturers typically make a plurality of semiconductor components from a single semiconductor wafer. The number of integrated circuits that can be manufactured from the single semiconductor wafer ranges from one up to hundreds of thousands. Because integrated circuits are comprised of transistors or semiconductor devices, one technique for lowering the cost of manufacturing an integrated circuit is to shrink the sizes of the transistors making up the integrated circuits. In addition to lowering costs, shrinking the device sizes increases their operating speeds.

Although the smaller transistors are capable of operating at increased speeds, other performance parameters may be degraded. For example, dual bit memory devices use a silicon-oxide-nitride-oxide-silicon (SONOS) type architecture in which a lower layer of silicon oxide is formed over a semiconductor substrate that is typically silicon. A layer of silicon nitride is formed on the lower layer of silicon oxide, an upper layer of silicon oxide is formed on the layer of silicon nitride and a layer of an electrically conductive material is formed on the upper layer of silicon oxide. The combination of the lower silicon oxide layer, the silicon nitride layer, and the upper silicon oxide layer are capable of trapping charge and are commonly referred to as a charge trapping dielectric structure or layer. When more than one bit of information is stored in the charge trapping structure, the memory device is referred to as a dual bit memory device. Bitlines are typically formed in the portion of the semiconductor substrate that is below the charge trapping structure and wordlines may be formed from the layer of electrically conductive material that is disposed on the charge trapping structure. In a dual bit memory device, two bits are stored per cell by biasing the bitline, the wordline, the source, and the drain of the memory cell such that a bit and a complementary bit are stored.

In shrinking this type of memory device, the bitlines may be formed closer together which shortens the lengths of the channels between adjacent bitlines. As the channel lengths are decreased, isolating the charge or bits stored in the charge trapping structure becomes increasingly difficult. For example, when programming the non-complementary bit, the complementary bit may become sufficiently charged to make it difficult to distinguish between the two bits during a read operation of the non-complementary bit. In addition, shrinking the memory devices may cause short channel effects and increase leakage currents.

Accordingly, what is needed is a memory device and a method for manufacturing the memory device that improves data retention and allows reducing the features sizes of a semiconductor device while mitigating adverse effects such as short channel effects.

### SUMMARY OF THE INVENTION

The present invention satisfies the foregoing need by providing a method for manufacturing a memory device that includes providing a semiconductor material having an active region and an isolation region. A charge trapping structure is formed over the active region and a first layer of semiconductor material is formed over the charge trapping structure. At least one masking structure having first and second sides is formed over the first layer of semiconductor material, wherein the at least one masking structure has first and second sides. At least one conductive strip having first and second sides is formed from the first layer of semiconductor material. A dielectric material is formed adjacent the first and second sides of the at least one conductive strip. A second layer of semiconductor material is formed over the at least one conductive strip and the dielectric material adjacent the first and second sides of the at least one conductive strip.

In accordance with another embodiment, the present invention comprises a method for manufacturing a memory device that includes forming a plurality of isolation structures in a semiconductor substrate such that a first active region of the semiconductor substrate is between first and second isolation structures of the plurality of isolation structures. A data retention structure is formed over at least the first active region. A first layer of semiconductor material is formed on the data retention structure. A hardmask is formed on the first layer of semiconductor material. The hardmask protects at least one portion of the first layer of semiconductor material and leaves at least one portion of the first layer of semiconductor material unprotected. The portions of the first layer of semiconductor material and the data retention structure that are unprotected by the hardmask are etched to expose a portion of the data retention structure and to form at least one conductive strip having first and second sides. A layer of dielectric material is formed over the at least one conductive strip and the exposed portion of the data retention structure. A second layer of semiconductor material is formed over the at least one conductive strip.

### BRIEF DESCRIPTION OF THE DRAWINGS

The present invention will be better understood from a reading of the following detailed description, taken in conjunction with the accompanying drawing figures in which like reference characters designate like elements and in which:

FIG. 1 is a cross-sectional side view of a semiconductor component at a beginning stage of manufacture in accordance with an embodiment of the present invention;

FIG. 2 is a cross-sectional side view of the semiconductor component of FIG. 1 at a later stage of manufacture;

FIG. 3 is a cross-sectional side view of the semiconductor component of FIG. 2 at a later stage of manufacture;

FIG. 4 is a cross-sectional side view of the semiconductor component of FIG. 3 at a later stage of manufacture;

FIG. 5 is a cross-sectional side view of the semiconductor component of FIG. 4 at a later stage of manufacture;

FIG. 6 is a cross-sectional side view of the semiconductor component of FIG. 5 at a later stage of manufacture;

FIG. 7 is a cross-sectional side view of the semiconductor component of FIG. 6 at a later stage of manufacture;

FIG. 8 is an isometric view taken in cross-section of the semiconductor component of FIG. 7 at a later stage of manufacture;

FIG. 9 is a cross-sectional side view of the semiconductor component of FIG. 4 at a later stage of manufacture in accordance with another embodiment of the present invention;

FIG. 10 is a cross-sectional side view of the semiconductor component of FIG. 9 at a later stage of manufacture;

FIG. 11 is a cross-sectional side view of the semiconductor component of FIG. 10 at a later stage of manufacture;

FIG. 12 is a cross-sectional side view of the semiconductor component of FIG. 11 at a later stage of manufacture;

FIG. 13 is a cross-sectional side view of the semiconductor component of FIG. 12 at a later stage of manufacture; and

FIG. 14 is an isometric view taken in cross-section of the semiconductor component of FIG. 13 at a later stage of manufacture.

### DETAILED DESCRIPTION

Generally, the present invention provides a method for manufacturing a memory device that isolates the charge trapping structure in a memory cell or device having, for example, a SONOS type architecture. The charge trapping structure is also referred to as a data retention structure. In accordance with an embodiment of the present invention, a gap-filling material is formed between memory cells to inhibit charge coupling between them. The gap-filling material may be formed either before or after removing a hardmask that defines the gate structure. The gap-filling material improves reliability and performance of the memory devices by maintaining the charge that has been stored in the charge storage region and inhibiting charge movement into the charge storage region during programming. It should be noted that the present invention may be used for memory devices having SONOS type architectures including NAND and NOR type configurations. In addition, the present invention is suitable for use with read only memories (ROMs), programmable read only memories (PROMs), erasable programmable read only memories (EPROMs), electrically erasable programmable read only memories (EEPROMs), or the like.

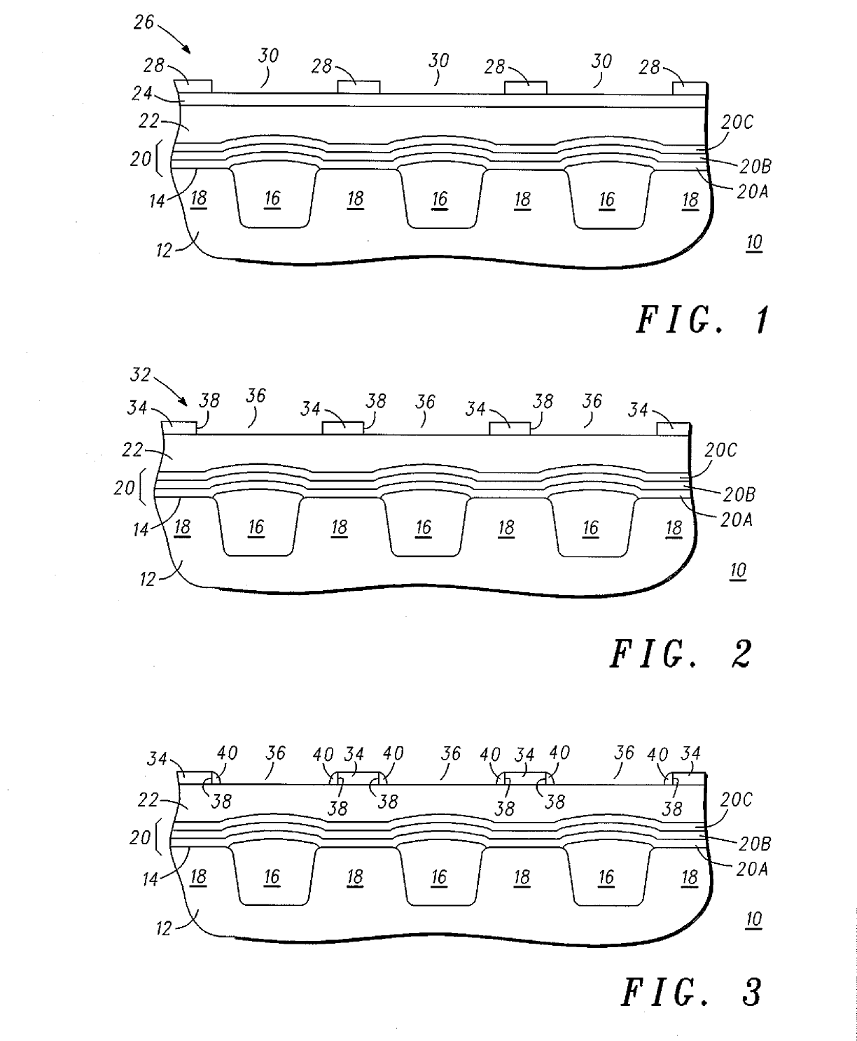

FIG. 1 is a cross-sectional side view of a portion of a semiconductor component 10 during manufacture in accordance with an embodiment of the present invention. What is shown in FIG. 1 is a substrate 12 having a major surface 14 and a plurality of Shallow Trench Isolation (“STI”) structures 16 formed therein. Techniques for forming STI structures 16 are known to those skilled in the art. Regions 18 that are between STI structures 16 are active regions, i.e., regions where the transistor action occurs. Suitable materials for substrate 12 include silicon, polysilicon, germanium, silicon germanium, Semiconductor-On-Insulator (“SOI”) material, and the like. In addition, substrate 12 can be comprised of a compound semiconductor material such as Group III-V semiconductor materials, Group II-VI semiconductor materials, etc. The conductivity type of substrate 12 is not a limitation of the present invention. In accordance with this embodiment, the conductivity type is chosen to form an N-channel insulated gate field effect transistor or semiconductor device. However, the conductivity type can be selected to form a P-channel insulated gate semiconductor device or a complementary insulated gate semiconductor device, e.g., a Complementary Metal Oxide Semiconductor (“CMOS”) device.

A charge trapping structure 20 is formed on active regions 18 and STI structures 16. In accordance with one embodiment, charge trapping structure 20 comprises three dielectric layers 20A, 20B, and 20C having a total thickness ranging from approximately 60 Angstroms (Å) to approximately 450 Å, wherein dielectric layer 20A is disposed on active regions 18 and STI structures 16, dielectric layer 20B is disposed on dielectric layer 20A, and dielectric layer 20C is disposed on dielectric layer 20B. By way of example, dielectric layer 20A is silicon dioxide having a thickness ranging from approximately 20 Å to approximately 150 Å, dielectric layer 20B is silicon nitride having a thickness ranging from approximately 20 Å to approximately 150 Å, and dielectric layer 20C is silicon dioxide having a thickness ranging from approximately 20 Å to approximately 150 Å. As those skilled in the art are aware, charge trapping occurs in silicon nitride layer 20B. In accordance with one embodiment, dielectric layers 20A and 20C have a thickness ranging from approximately 50 Å to approximately 150 Å and dielectric layer 20B has a thickness ranging from approximately 20 Å to approximately 80 Å.

Alternatively, one or both of dielectric layers 20A and 20C may be silicon dioxide layers that are silicon-rich silicon dioxide layers; one or both of dielectric layers 20A and 20C may be silicon dioxide layers that are oxygen-rich silicon dioxide layers; one or both of dielectric layers 20A and 20C may be thermally grown or deposited oxide layers; and one or both of dielectric layers 20A and 20C may be silicon dioxide layers that are nitrided oxide layers. Dielectric layer 20B may be a silicon-rich silicon nitride layer or a nitrogen-rich silicon nitride layer.

It should be understood that charge trapping structure 20 is not limited to being a three layer structure or a structure limited to silicon dioxide and silicon nitride. Charge trapping structure 20 may be any dielectric layer or layers capable of trapping charge or that facilitate charge trapping. Other suitable materials for charge trapping structure 20 include an oxide/nitride bilayer dielectric, a nitride/oxide bilayer dielectric, an oxide/tantalum oxide bilayer dielectric (SiO₂/Ta₂O₅), an oxide/tantalum oxide/oxide trilayer dielectric (SiO₂/Ta₂O₅/SiO₂), an oxide/strontium titanate bilayer dielectric (SiO₂/SrTiO₃), an oxide/barium strontium titanate bilayer dielectric (SiO₂/BaSrTiO₂), an oxide/strontium titanate/oxide trilayer dielectric, an oxide/strontium titanate/oxide trilayer dielectric (SiO₂/SrTiO₃/BaSrTiO₂), an oxide/hafnium oxide/oxide trilayer dielectric, and the like. Although not shown, it should be understood that a tunnel oxide may be formed between semiconductor substrate 12 and charge trapping structure 20.

Still referring to FIG. 1, a layer of semiconductor material 22 having a thickness ranging from approximately 300 Å to approximately 15,000 Å is deposited over charge trapping structure 20. In accordance with one embodiment semiconductor layer 22 is polysilicon. Other suitable semiconductor materials for semiconductor layer 22 include doped polysilicon, doped amorphous silicon, or the like. A layer of dielectric material 24 having a thickness ranging from approximately 300 Å to approximately 10,000 Å is formed on polysilicon layer 22. Preferably dielectric material 24 is silicon nitride. A layer of photoresist is formed on dielectric layer 24 and patterned to form an etch mask 26 comprising masking structures 28 and openings 30. Masking structures 28 are above active regions 18 and openings 30 are above STI structures 16. The portions of dielectric layer 24 covered by masking structures 28 are protected by etch mask 26 and the portions of dielectric layer 24 exposed by openings 30 are unprotected by etch mask 26.

Referring now to FIG. 2, the portions of dielectric layer 24 unprotected by etch mask 26 are etched away using, for example, a Reactive Ion Etch (“RIE”) that stops or terminates on polysilicon layer 22. The reactive ion etch forms a hardmask 32 comprising masking structures 34 and openings 36 that expose portions of polysilicon layer 22. Masking structures 34 have sidewalls 38.

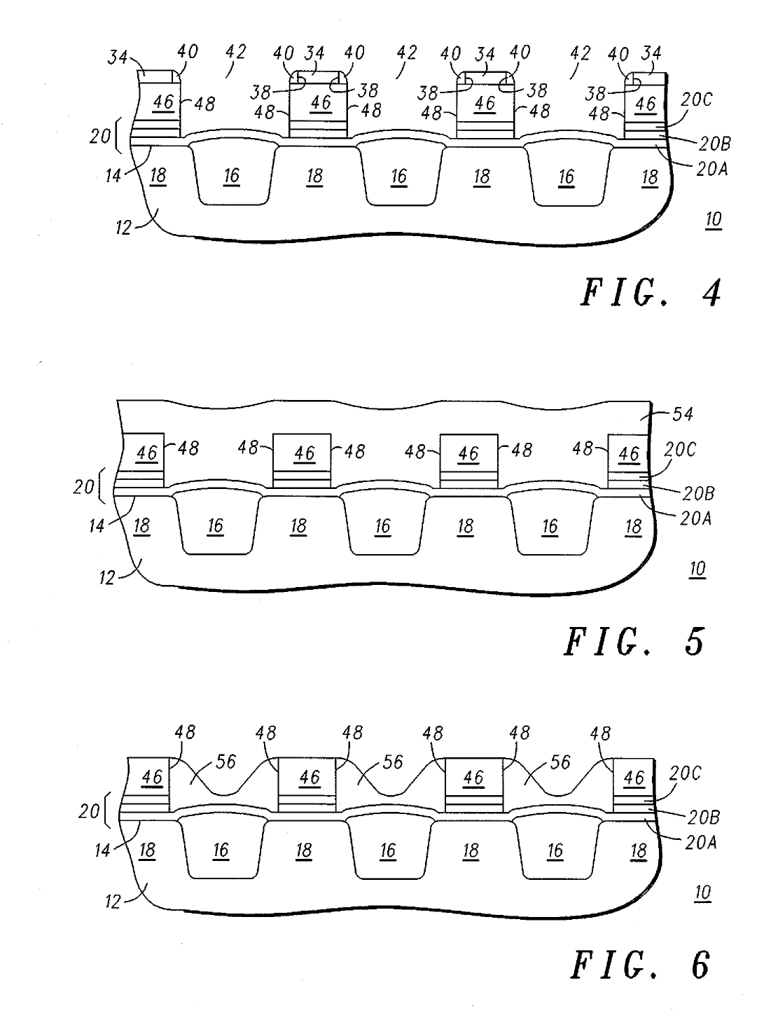

Referring now to FIG. 3, a layer of dielectric material is formed on hardmask 32 and the exposed portions of polysilicon layer 22. The layer of dielectric material is anisotropically etched to form spacers 40 adjacent sidewalls 38. Preferably, the material of spacers 40 is the same material as that of masking structures 34. Even more preferably, masking structures 34 and spacers 40 are silicon nitride. It should be noted that masking structures 34 and spacers 40 protect the portions of polysilicon layer 22, silicon dioxide layer 20C and silicon nitride layer 20B that are below them, whereas the portions of polysilicon layer 22, silicon dioxide layer 20C and silicon nitride layer 20B that are not below masking structures 34 and spacers 40 are unprotected. In accordance with one embodiment, the distance between spacers 40 within the same opening 36 ranges from approximately 50 nanometers (nm) to approximately 150 nm. By way of example, the distance is approximately 70 mm.

Referring now to FIG. 4, the portions of polysilicon layer 22, oxide layer 20C, and silicon nitride layer 20B that are unprotected by masking structures 34 and spacers 40 are anisotropically etched using, for example, a reactive ion etch. It should be noted that the type of etch is not a limitation of the present invention. Thus, the portions of polysilicon layer 22, oxide layer 20C, and silicon nitride layer 20B that are unprotected by masking structures 34 and spacers 40 can be etched using a wet etch, a dry etch, or a combination of a wet etch and a dry etch. The anisotropic etch stops in or on silicon dioxide layer 20A. The anisotropic etch forms openings 42 in polysilicon layer 22, silicon dioxide layer 20C, and silicon nitride layer 20B. In addition, the anisotropic etch forms polysilicon fingers 46 from polysilicon layer 22, wherein polysilicon fingers 46 have sidewalls 48. The polysilicon fingers are also referred to as conductive strips, conductive fingers, or conductive structures. In accordance with an embodiment in which the distance between spacers 40 that are within the same opening 36 is approximately 70 nm, the distance between adjacent polysilicon fingers is approximately 70 nm. It should be noted that FIGS. 1-7 are two dimensional views and that polysilicon fingers 46 are preferably rectangular, i.e., they extend into the plane of the paper.

Referring now to FIG. 5, hardmask 32 and spacers 40 are removed using, for example, a reactive ion etch. It should be noted that the type of etch is not a limitation of the present invention. Thus, hardmask 32 and spacers 40 can be etched using a wet etch, a dry etch, or a combination of a wet etch and a dry etch. A layer of dielectric material 54 is formed on polysilicon fingers 46 and in openings 42. Preferably dielectric material 54 is oxide formed by the decomposition of tetraethylorthosilicate, i.e., formed using a TEOS process. The method of forming dielectric layer 54 is not a limitation of the present invention. Other suitable methods for forming dielectric layer 54 include a High Temperature Oxidation (HTO) process, a Rapid Thermal Oxidation (RTO) process, or the like.

Referring now to FIG. 6, oxide layer 54 is etched using a blanket oxide etch back technique leaving a gap-filling material 56 adjacent sidewalls 48. Alternatively, oxide layer 54 can be etched using a Chemical Mechanical Planarization (“CMP”) technique.

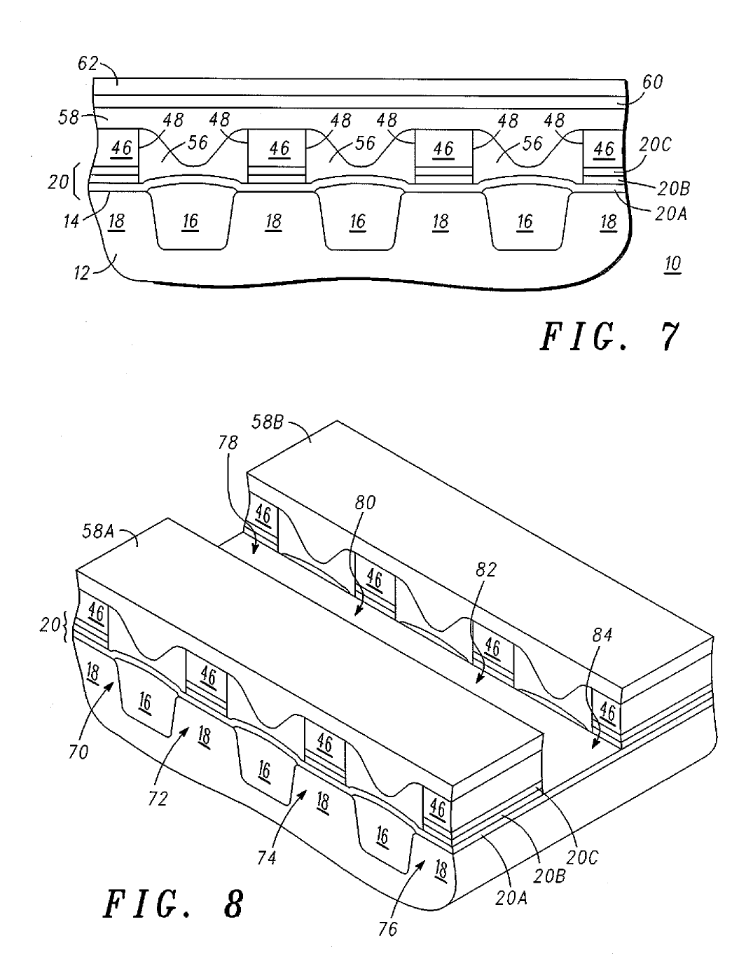

Referring now to FIG. 7, polysilicon fingers 46 are cleaned to remove native oxide that may have formed on them using techniques known to those skilled in the art. Preferably, the clean is tailored so that gap-filling material 56 is not gouged or damaged. A layer of polysilicon 58 is formed on polysilicon fingers 46 and gap-filling material 56. Preferably, polysilicon layer 58 has a thickness of less than about 1,500 Å. Polysilicon layer 58 is planarized using, for example, a CMP technique. Other suitable planarization techniques include electropolishing, electrochemical polishing, chemical polishing, and chemically enhanced planarization. Layer 58 is not limited to being polysilicon. Other suitable materials for layer 58 include amorphous silicon, silicon carbide, gallium arsenide, indium phosphide, and the like.

An anti-reflective coating 60 is formed on polysilicon layer 58. By way of example, anti-reflective coating 60 is silicon nitride having a thickness ranging from approximately 100 Å to approximately 3,000 Å. A layer of photoresist 62 is formed on anti-reflective coating 60.

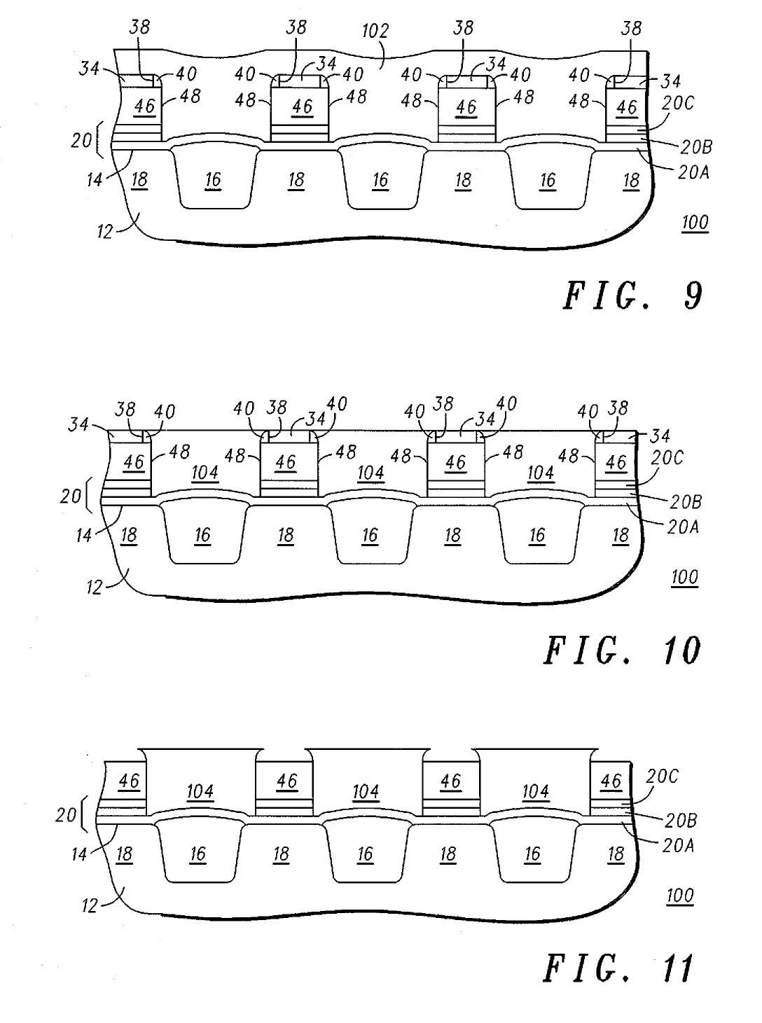

Referring now to FIG. 8, an isometric view of semiconductor component 10 is shown further along in processing. It should be noted that FIG. 8 is shown as an isometric view to facilitate the description of the manufacture of semiconductor component 10. Photoresist layer 62 is patterned on anti-reflective coating 60 to form an etch mask layer. Anti-reflective coating 60, polysilicon layer 58, polysilicon layer 22, and dielectric layers 20B and 20C are anisotropically etched. After etching polysilicon layer 62, the etch chemistry is modified to etch polysilicon fingers 46 to form memory devices 70, 72, 74, 76, 78, 80, 82, and 84. The etch mask layer and the anti-reflective coating are removed. The remaining portions 58A and 58B of polysilicon layer 58 serve as word lines. Preferably, wordlines 58A and 58B are substantially perpendicular to polysilicon fingers 46.

Although not shown, it should be understood that source and drain regions are formed in active regions 18 of substrate 12 and that additional processing is typically performed to form a metallization system including contact structures.

Referring now to FIG. 9, a semiconductor component 100 is shown at an intermediate stage of manufacture in accordance with another embodiment of the present invention. It should be noted that FIG. 9 continues from the description of FIG. 4. A layer of dielectric material 102 having a thickness ranging from approximately 100 Å to approximately 15,000 Å is formed on polysilicon fingers 46 and in openings 42. Preferably dielectric material 102 is oxide formed by the decomposition of tetraethylorthosilicate, i.e., formed using a TEOS process. The method of forming dielectric layer 102 is not a limitation of the present invention. Other suitable methods for forming dielectric layer 102 include a High Temperature Oxidation (HTO) process, a Rapid Thermal Oxidation (RTO) process, or the like.

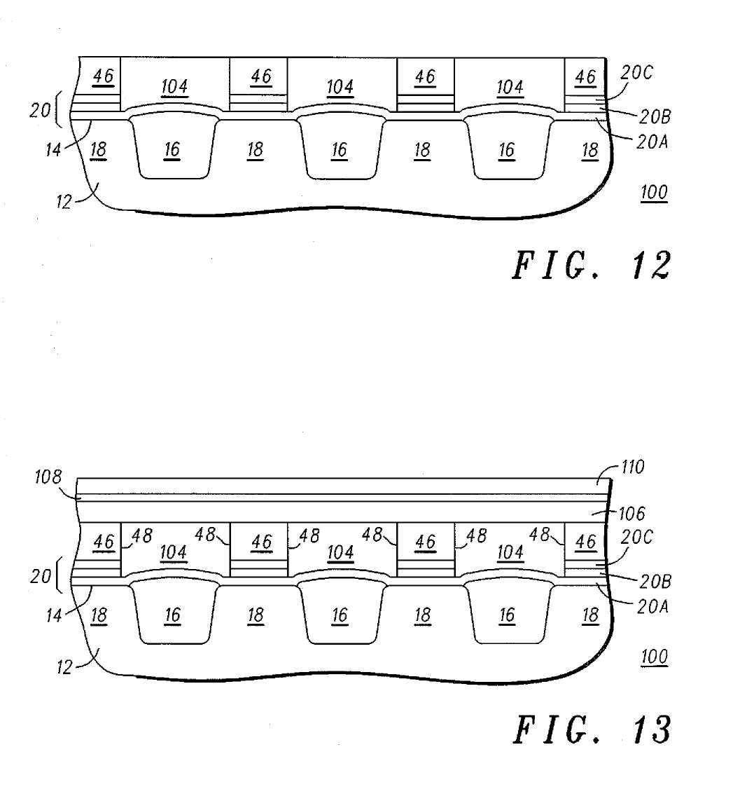

Referring now to FIG. 10, oxide layer 102 is etched using a blanket oxide etch back technique to form oxide plugs 104 from oxide layer 102 that are between or adjacent corresponding sidewalls 48. Oxide plugs 104 serve as a gap-filling material. Alternatively, oxide layer 102 can be etched using a CMP technique.

Referring now to FIG. 11, masking structures 34 are removed using a wet etch such as, for example, a wet hydrofluoric acid (HF) etch or a wet phosphoric acid (H₃PO₄) etch. Removing masking structures 34 leaves portions of oxide plugs 104 extending above polysilicon fingers 46.

Referring now to FIG. 12, oxide plugs 104 are planarized such that they are substantially co-planar with polysilicon fingers 46.

Referring now to FIG. 13, polysilicon fingers 46 are cleaned to remove native oxide that may have formed on them using techniques known to those skilled in the art. Preferably, the clean is tailored so that oxide plugs 104 are not gouged or damaged. A layer of polysilicon 106 is formed on polysilicon fingers 46 and oxide plugs 104. Preferably, polysilicon layer 106 has a thickness of less than about 1,500 Å. Polysilicon layer 106 is planarized using, for example, a CMP technique. Other suitable planarization techniques include electropolishing, electrochemical polishing, chemical polishing, and chemically enhanced planarization. Layer 106 is not limited to being polysilicon. Other suitable materials for layer 106 include amorphous silicon, silicon carbide, gallium arsenide, indium phosphide, and the like.

An anti-reflective coating 108 is formed on polysilicon layer 106. By way of example, anti-reflective coating 108 is silicon nitride having a thickness ranging from approximately 100 Å to approximately 3,000 Å. A layer of photoresist 10 is formed on anti-reflective coating 108.

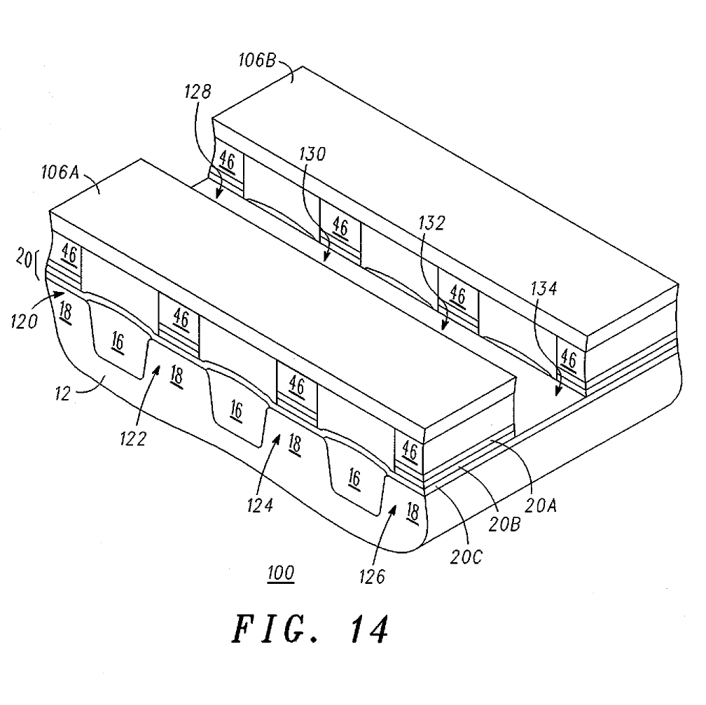

Referring now to FIG. 14, an isometric view of semiconductor component 100 is shown further along in processing. It should be noted that FIG. 14 is shown as an isometric view to facilitate the description of the manufacture of semiconductor component 100. Photoresist layer 110 is patterned on anti-reflective coating 108 to form an etch mask layer. Anti-reflective coating 108, polysilicon layer 106, polysilicon layer 22, and dielectric layers 20B and 20C are anisotropically etched. After etching polysilicon layer 106, the etch chemistry is modified to etch polysilicon fingers 46. Then the etch chemistry is changed to form floating gate memory devices 120, 122, 124, 126, 128, 130, 132, and 134. The etch mask layer and the anti-reflective coating are removed. The remaining portions 106A and 106B of polysilicon layer 106 serve as word lines. Preferably, wordlines 106A and 106B are substantially perpendicular to polysilicon fingers 46.

Although not shown, it should be understood that source and drain regions are formed in active regions 18 of substrate 12 and that additional processing is typically performed to form a metallization system including contact structures.

By now it should be appreciated that memory device and a method for manufacturing the memory device have been provided. An advantage of the present invention is that it maintains the integrity of the charge stored in the charge storage region and therefore improves data retention. Another advantage is that the process flow for manufacturing the memory devices in accordance with the present invention can be integrated into a variety of process flows in a cost efficient manner.

Although certain preferred embodiments and methods have been disclosed herein, it will be apparent from the foregoing disclosure to those skilled in the art that variations and modifications of such embodiments and methods may be made without departing from the spirit and scope of the invention. For example, the semiconductor devices can be electrically isolated from each other using LOCOS isolation structures rather than STI structures. It is intended that the invention shall be limited only to the extent required by the appended claims and the rules and principles of applicable law.

What is claimed is:

1. A method for manufacturing a memory device, comprising:
providing a semiconductor material having an active region and an isolation region;
forming a charge trapping structure over the active region;
forming a first layer of semiconductor material over the charge trapping structure;
forming at least one masking structure over the first layer of semiconductor material, the at least one masking structure having first and second sides;
forming at least one conductive strip from the first layer of semiconductor material, the at least one conductive strip having first and second sides;
forming a dielectric material adjacent the first and second sides of the at least one conductive strip; and
forming a second layer of semiconductor material over the at least one conductive strip and the dielectric material adjacent the first and second sides of the at least one conductive strip.

2. The method of claim 1, wherein forming the charge trapping structure includes forming a silicon rich nitride layer.

3. The method of claim 1, wherein forming the at least one masking structure comprises:
forming a layer of nitride on the first layer of polysilicon;
forming an etch mask on the layer of nitride, wherein the etch mask leaves a portion of the layer of nitride unprotected; and
etching the portion of the layer of nitride that is unprotected by the etch mask.

4. The method of claim 3, wherein forming the at least one masking structure further includes forming first and second sidewall spacers adjacent the first and second sides of the masking structure, respectively.

5. The method of claim 1, wherein forming the charge trapping structure over the active region comprises:
forming a first oxide layer on the active region;
forming a first nitride layer on the first oxide layer; and
forming a second oxide layer on the first silicon nitride layer.

6. The method of claim 5, wherein forming the at least one dielectric mask structure comprises:
forming a layer of nitride on the first layer of polysilicon;
forming an etch mask on the layer of nitride, wherein the etch mask leaves a portion of the layer of nitride unprotected; and
etching the portion of the layer of nitride that is unprotected by the etch mask.

7. The method of claim 6, further including forming first and second sidewall spacers adjacent the first and second sides of the at least one masking structure, respectively.

8. The method of claim 6, wherein etching the portion of the layer of nitride that is unprotected by the etch mask includes exposing a portion of the first layer of dielectric material.

9. The method of claim 8, wherein forming the dielectric material adjacent the first and second sides of the at least one conductive strip includes forming oxide adjacent the first and second sides of the at least one conductive strip.

10. The method of claim 9, further including forming at least one conductive strip from the second layer of semiconductor material.

11. The method of claim 10, wherein the at least one conductive strip formed from the second layer of conductive material is substantially perpendicular to the at least one conductive strip formed from the first layer of conductive material.

12. The method of claim 1, further including removing the at least one masking structure after forming the dielectric material adjacent the first and second sides of the at least one conductive strip.

13. The method of claim 12, further including removing the at least one masking structure before forming the dielectric material adjacent the first and second sides of the at least one conductive strip.

14. A method for manufacturing a memory device, comprising:
providing a semiconductor substrate;
forming a plurality of isolation structures in the semiconductor substrate, wherein a first active region of the semiconductor substrate is between first and second isolation structures of the plurality of isolation structures;
forming a data retention structure over at least the first active region;
forming a first layer of semiconductor material on the data retention structure;
forming a hardmask on the first layer of semiconductor material, wherein the hardmask protects at least one portion of the first layer of semiconductor material and leaves at least one portion of the first layer of semiconductor material unprotected;
etching the first layer of semiconductor material and the data retention structure that are unprotected by the hardmask to expose a portion of the data retention structure and to form at least one conductive strip from the first layer of semiconductor material, the at least one conductive strip having first and second sidewalls;
forming a layer of dielectric material over the at least one conductive strip and the exposed portion of the data retention structure; and
forming a second layer of semiconductor material over the at least one conductive strip.

15. The method of claim 14, wherein forming the hardmask on the first layer of semiconductor material includes forming the hardmask to have first and second sidewalls and further including forming first and second sidewall spacers adjacent the first and second sidewalls, respectively.

16. The method of claim 14, wherein forming the layer of dielectric material over the at least one conductive strip and the exposed portion of the dielectric structure includes forming a gap-filling material adjacent the first and second sidewalls of the at least one conductive strip.

17. The method of claim 14, further including forming at least one conductive strip from the second layer of semiconductor material, the at least one conductive strip formed from the second layer of semiconductor material substantially perpendicular to the at least one conductive strip formed from the first layer of semiconductor material.

18. The method of claim 14, further including removing the hardmask after forming a layer of dielectric material over the at least one conductive strip formed from the first layer of semiconductor material and over the exposed portion of the data retention structure, wherein removing the hardmask exposes the at least one conductive strip formed from the first layer of semiconductor material.

19. The method of claim 14, wherein forming the data retention structure includes:
forming first oxide layer on the first active region;
forming a nitride layer on the first oxide layer; and
forming a second oxide layer on the nitride layer.

20. The method of claim 19, wherein etching the first layer of semiconductor material and the data retention structure that are unprotected by the hardmask to expose a portion of the data retention structure includes exposing the first oxide layer.
